(19) United States
(12) Patent Application Publication
(10) Pub. No.: US 2011/0260581 A1
(43) Pub. Date: Oct. 27, 2011

(54) Flexible Phased Array Sensor

(75) Inventors: Anindya Ghoshal, Towson, MD (US); Zaffir A. Chaudhry, S. Glastonbury, CT (US); Fanping Sun, Glastonbury, CT (US)

(73) Assignee: SIKORSKY AIRCRAFT CORPORATION, Stratford, CT (US)

(21) Appl. No.: 13/093,318

(22) Filed: Apr. 25, 2011

Related U.S. Application Data
(60) Provisional application No. 61/328,420, filed on Apr. 27, 2010.

(51) Int. Cl. H01L 41/04

(52) U.S. Cl. 310/323.21

(57) ABSTRACT

A sensor includes a film, at least one piezoelectric strip disposed on the film, a first conductive line disposed on the film, the first conductive line electrically connected to a first portion of the at least one piezoelectric strip, a second conductive line disposed on the film, the second conductive line electrically connected to a second portion of the at least one piezoelectric strip, and a dampening member disposed on the at least one piezoelectric strip.

### BACKGROUND OF THE INVENTION

The subject matter disclosed herein relates to phased array sensors.

Phased array sensors use multiple ultrasonic elements that are actuated by electronic time delay circuits to create sonic beams using constructive and destructive interference. Phased array sensors are useful in, for example, non-destructive testing and analysis of materials such as metals, or composite materials such as fiberglass, carbon fiber composites, or Kevlar composites. Acoustic beams forming from a phased array may be manipulated electronically to steer, scan, sweep, or focus the beams on an area of interest.

In the aircraft industry, for example, a hand held sensor may be placed on a portion of an aircraft. The sensor may be used to identify or localize cracks, corrosion zones, or delaminations in a metallic or composite material. Typical sensors are bulky and rigid devices that are ill-suited for use during the operation of the aircraft. The typical sensors are also cumbersome to use when analyzing curved surfaces since the typical sensor is most effective when placed on a flat surface. Previous methods for analyzing a curved surface included fabricating a purpose built jig having a curved face that was placed on the curved surface, and an opposing flat face that fit the sensor.

### BRIEF DESCRIPTION OF THE INVENTION

According to one aspect of the invention, a sensor includes a film, at least one piezoelectric strip disposed on the film, a first conductive line disposed on the film, the first conductive line electrically connected to a first portion of the at least one piezoelectric strip, a second conductive line disposed on the film, the second conductive line electrically connected to a second portion of the at least one piezoelectric strip, and a dampening member disposed on the at least one piezoelectric strip.

According to another aspect of the invention, a method for fabricating a sensor includes patterning a first conductive line and a second conductive line on a film, electrically connecting a first portion of a piezoelectric strip to the first conductive line with a conductive adhesive, electrically connecting a second portion of the piezoelectric strip to the second conductive line with a conductive adhesive, and attaching a dampening member to the piezoelectric strip.

These and other advantages and features will become more apparent from the following description taken in conjunction with the drawings.

### BRIEF DESCRIPTION OF THE DRAWINGS

The subject matter which is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 illustrates a partially cut-away top view of an exemplary embodiment of a flexible phased array sensor

FIG. 2 illustrates a side view of the sensor of FIG. 1.

FIGS. 3-6 illustrate exemplary dimensions of the sensor of FIG. 1

FIG. 7 illustrates a block diagram of an exemplary embodiment of a sensor system.

FIG. 8 illustrates a side view of an example of a sensor disposed on a convex surface.

FIG. 9 illustrates a side view of an example of a sensor disposed on a concave surface.

FIG. 10 illustrates a side view of another example of a sensor disposed on a concave surface.

FIGS. 11 and 12 illustrate a top view and cross-sectional of a sensor disposed in a composite material respectively.

The detailed description explains embodiments of the invention, together with advantages and features, by way of example with reference to the drawings.

### DETAILED DESCRIPTION OF THE INVENTION

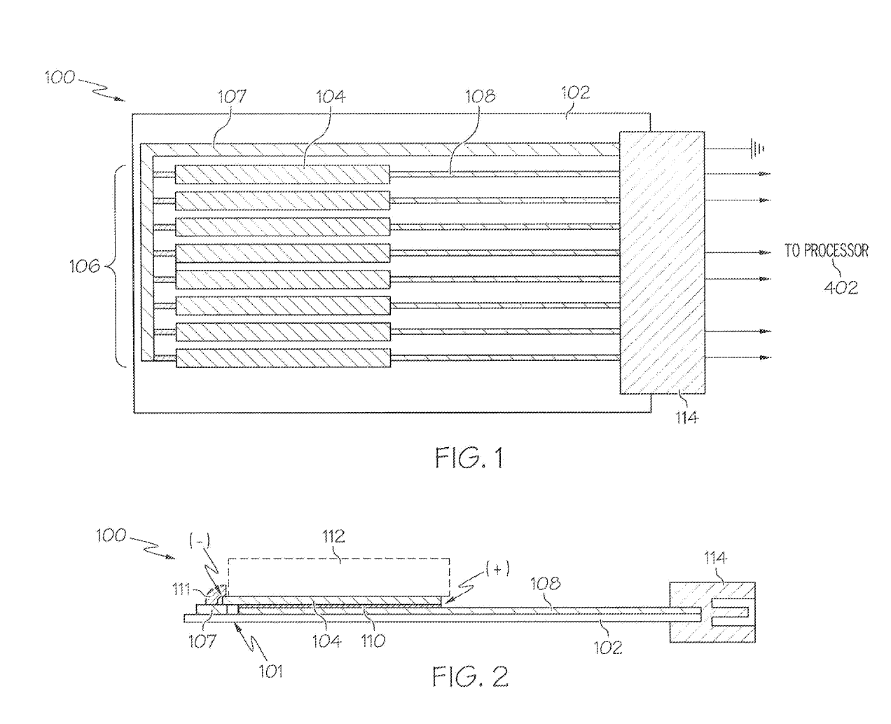

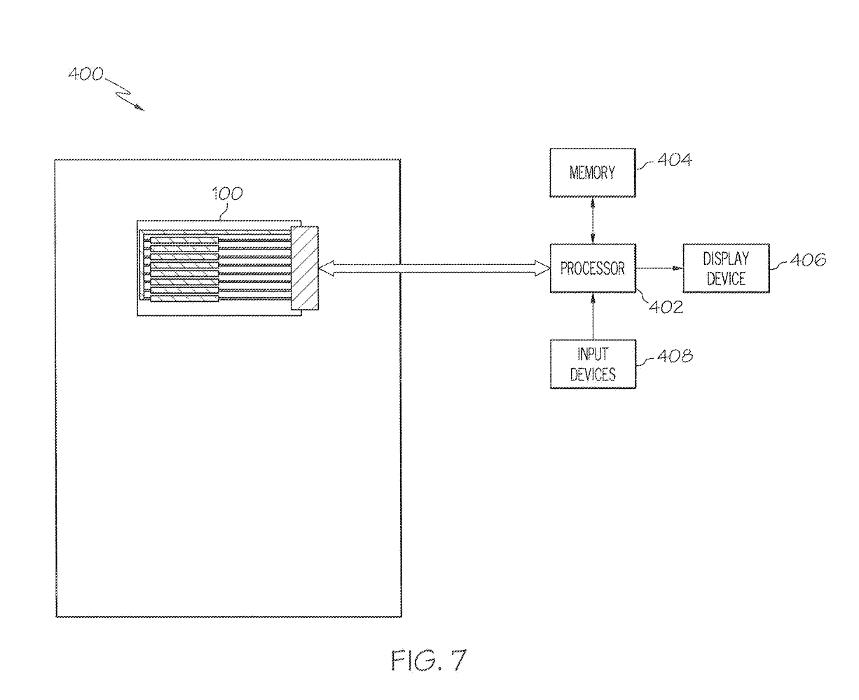

FIGS. 1 and 2 illustrate a partially cut-away top view and a side view respectively of an exemplary embodiment of a flexible phased array sensor (sensor) 100. The sensor 100 includes a flexible polyimide film (film) 102. The polyimide film includes flexible polymer of imide monomers that is non-conductive. A plurality of piezoelectric strips 104 form an array of piezoelectric transducers (array) 106. The piezoelectric transducers 106 may be formed from, for example, lead zirconate titanate, barium titanate, piezoecomposite materials, soft piezoelectric materials, or any other type of appropriate piezoelectric material. Each piezoelectric strip 104 is electrically connected to a processor 402 (shown in FIG. 7, and described below) and ground via conductive lines (lines) that are disposed on the film 102. The sensor 100 includes lines 108 that are connected to the processor 402, and lines 107 that are connected to ground. The lines may be patterned using, for example, a lithographic etching process that patterns a metallic conductor material such as, for example, copper or silver on the film 102. A portion of the piezoelectric strips 104 are connected to the lines 108 with a conductive adhesive material 110. Such as, for example, a silicon adhesive. The conductive adhesive material secures the piezoelectric strips 104 to the lines 108 and the film 102. Referring to the side view A-A, a positive end (+) of the piezoelectric strip 104 is connected to the line 108 that is connected to the processor 402. A gap 101 is defined by the line 108 and the line 107. A portion of the negative end (−) of the piezoelectric strip 104 is disposed across the gap 101 and is connected to ground via the line 107 and secured to the line 107 with conductive adhesive material 111. A damping member 112 is disposed on the piezoelectric strips 104 and may be attached with an adhesive or epoxy. The damping member 112 is a thin, flexible damping material such as, for example, a vinyl solid thermoplastic material that has low rebound characteristics, with low amplification at resonance and rapid settling to equilibrium after a vibration input. A connector 114 such as, for example, a plastic male or female snap-together connector may be attached to the film 102 and the lines 107 and 108 to allow the sensor 100 to be easily connected and disconnected to the processor 402 (of FIG. 7). In the illustrated exemplary embodiment, a Joint Test Action Group (JTAG) type connector is shown.

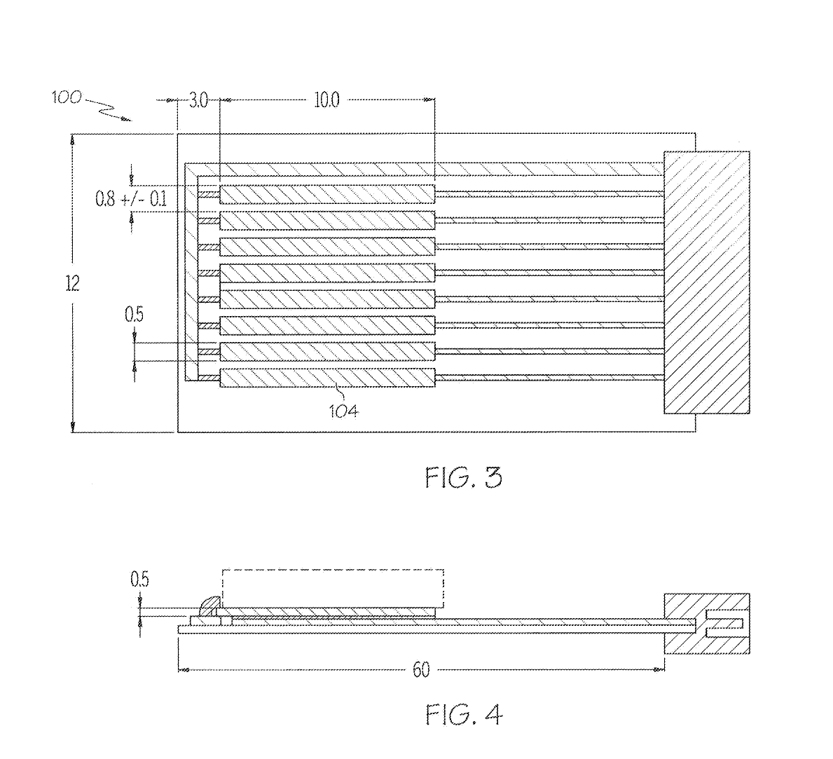

FIGS. 3 and 4 illustrate exemplary dimensions of the sensor 100 in millimeters (mm) In the illustrated embodiment, the piezoelectric strips 104 are 0.5 mm wide and have edges spaced at approximately 0.8 mm apart. The piezoelectric strips 104 are shown as being 0.5 mm thick and 10 mm long, but may range between 0.01 to 1.0 mm thick and between 9 and 11 mm long. The film 102 is approximately 0.127 mm thick but may range from 0.01 to 1.0 mm thick. The dampening member 112 is approximately 2.0 mm thick but may range from 1.0 to 2.5 mm thick.

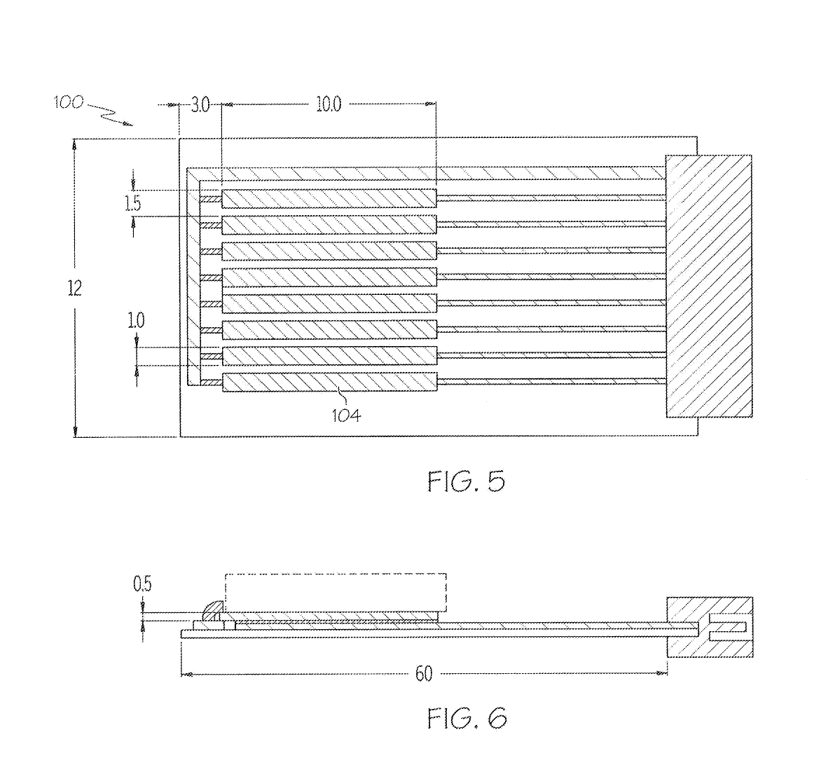

FIGS. 5 and 6 illustrate alternate exemplary dimensions of the sensor 100 in millimeters. In the illustrated embodiment, the sensor 100 is similar to the sensor 100 of FIG. 2 however, the piezoelectric strips 104 are 1.0 mm wide and have edges spaced at approximately 1.5 mm apart.

The dimensions shown in FIGS. 2 and 3 are merely examples; alternate embodiments of the sensor 100 described above may include any range of dimensions, and may include one or more arrays 106 having any number of piezoelectric strips 104 and any number of connectors 114.

FIG. 7 illustrates a block diagram of an exemplary embodiment of a sensor system 400. The system 400 includes a sensor 100 shown disposed on a material 401. The sensor 100 is communicatively connected to a processor 402 with an input/output cable via the connector 114 (of FIG. 1). The processor 402 may be connected to a memory 404, a display device 406, and input devices 408. The processor is operative to control the sensor 100 by inducing voltages across the sensor 100, and receiving and measuring voltages output by the sensor 100.

When disposed on a planar surface, the sensor 100 operates by receiving an input signal from the processor 402. The voltage from the input signal interacts with the piezoelectric material in the sensor 100 to emit an acoustic wave into a sensed material. The reflection of the acoustic wave is sensed by the piezoelectric material of the sensor 100. The sensor 100 outputs a voltage to the processor 402. The size and flexibility of the sensor 100 allows one or more of the sensors 100 to be attached to a surface of or embedded in mechanical components of an operating system such as, for example, an aircraft. The sensors 100 may be used, for example, to collect real-time data of an operating system.

FIG. 8 illustrates a side view of an example of the sensor 100 disposed on a convex surface 500. A clamping device 502 such as, for example a pneumatic or hydraulic bladder that is held in place by a second clamp 504, applies pressure to the sensor 100. The pressure applied to the sensor 100 bends the sensor 100 to conform to the convex surface 500.

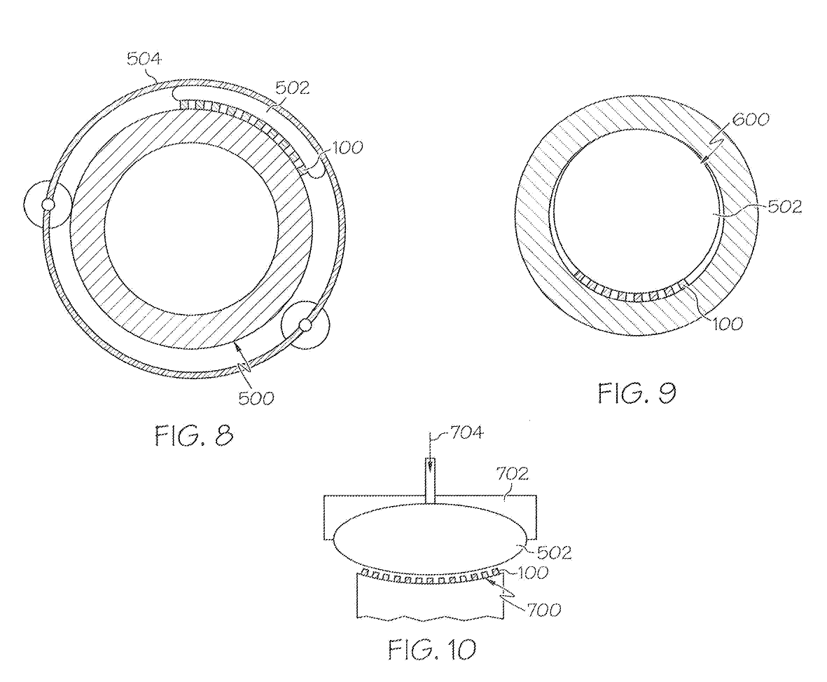

FIG. 9 illustrates a side view of an example of the sensor 100 disposed on a concave surface 600. The sensor 100 is held in place by the clamping device 502 that bends the sensor 100 to conform to the concave surface 600.

FIG. 10 illustrates a side view of another example of the sensor 100 disposed on a concave surface 700. In the illustrated embodiment, the clamping device 502 is held in place with a second clamp 702, and the clamping device 502 applies pressure to bend the sensor 100 when compressed air 702 fills the clamping device 502. Though the illustrated embodiments include clamping devices 502 that operate using pneumatic or hydraulic pressure, any type of clamping device may be used to conform the sensor 100 to a surface.

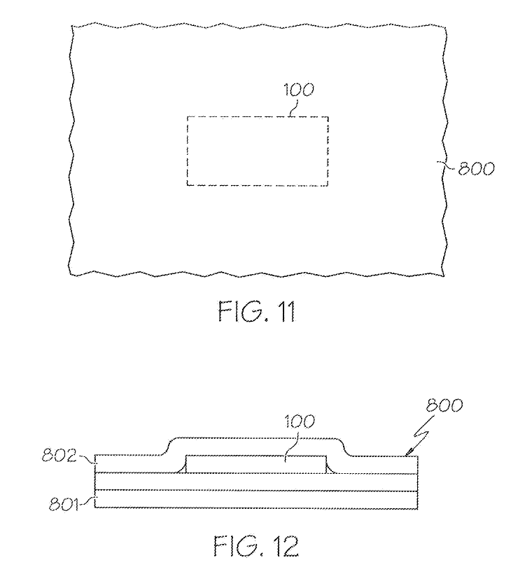

FIG. 11 illustrates a top view and FIG. 12 illustrates a cross-sectional view of a sensor 100 disposed in a composite material 800. The composite material 800 may include a plurality of laminated layers of material. The material may include, for example, woven fiberglass, Kevlar, or carbon fiber fabric, or any other type of material that is bonded with an epoxy or adhesive. In fabrication, one or more sensors 100 may be disposed on or in the composite material 800. In the illustrated example, the sensor 100 is disposed on a first layer 801 and covered with a second layer 802.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A sensor including:
a film;
at least one piezoelectric strip disposed on the film;
a first conductive line disposed on the film, the first conductive line electrically connected to a first portion of the at least one piezoelectric strip;
a second conductive line disposed on the film, the second conductive line electrically connected to a second portion of the at least one piezoelectric strip; and
a dampening member disposed on the at least one piezoelectric strip.

2. The sensor of claim 1, wherein the film is a flexible polyimide material.

3. The sensor of claim 1, wherein the first conductive line is electrically connected to the first portion of the at least one piezoelectric strip with a conductive adhesive material.

4. The sensor of claim 1, wherein the second conductive line is electrically connected to the second portion of the at least one piezoelectric strip with a conductive adhesive material.

5. The sensor of claim 1, wherein the dampening member is a flexible vinyl thermoplastic material.

6. The sensor of claim 1, wherein the dampening member is attached to the least one piezoelectric strip with an adhesive material.

7. The sensor of claim 1, wherein the sensor further includes a connector operative to electrically and mechanically connect the first conductive line and the second conductive line to a cable.

8. The sensor of claim 1, wherein the first conductive line is electrically connected to ground.

9. The sensor of claim 1, wherein the second conductive line is electrically connected to a voltage source.

10. The sensor of claim 3, wherein the voltage source is a processor.

11. The sensor of claim 1, wherein the film is between 0.1 to 0.15 millimeters (mm) in thickness.

12. The sensor of claim 1, wherein the dampening member is between 1.8 to 2.2 mm in thickness.

13. The sensor of claim 1, wherein the at least one piezoelectric strip is between 0.4 to 0.6 mm in thickness.

14. The sensor of claim 1, wherein the at least one piezoelectric strip is between 0.4 to 0.6 mm in width.

15. A method for fabricating a sensor including:
patterning a first conductive line and a second conductive line on a film;
electrically connecting a first portion of a piezoelectric strip to the first conductive line with a conductive adhesive;
electrically connecting a second portion of the piezoelectric strip to the second conductive line with a conductive adhesive; and
attaching a dampening member to the piezoelectric strip.

16. The method of claim 15, wherein the first conductive line and the second conductive line are patterned on the film with a lithographic etching process.

17. The method of claim 15, wherein the dampening member is attached to the piezoelectric strip with an adhesive.

18. The method of claim 15, wherein the dampening member is attached to the piezoelectric strip and the film.

19. The method of claim 15, wherein the film is a flexible polyimide material.

20. The method of claim 15, wherein the dampening member is a flexible vinyl thermoplastic material.
